(19) United States
(12) Patent Application Publication
(10) Pub. No.: US 2024/0413178 A1
(43) Pub. Date: Dec. 12, 2024

(54) SENSOR PROTECTION OF GLASSLESS WAFER-LEVEL OPTICAL SENSOR PACKAGING

(71) Applicant: STMICROELECTRONICS INTERNATIONAL N.V., Geneva (CH)

(72) Inventor: Rita KUO, Taoyuan (TW)

(21) Appl. No.: 18/674,220

(22) Filed: May 24, 2024

Related U.S. Application Data
(60) Provisional application No. 63/507,345, filed on Jun. 9, 2023.

(51) Int. Cl. H01L 27/146; H01L 23/00

(52) U.S. Cl. CPC H01L 27/14618; H01L 23/562; H01L 27/14683

(57) ABSTRACT

A glassless wafer-level optical sensor semiconductor package is provided. A method of manufacturing a glassless wafer-level optical sensor package of an example includes: forming one or more dams at least partially surrounding one or more optical sensors on a wafer; supporting the wafer on a carrier substrate via the one or more dams; forming a wafer-level optical sensor integrated circuit for each of the one or more optical sensors on the wafer by: performing a through-silicon via process on the wafer; forming an isolation layer on the wafer; and performing a passivation operation on the wafer; removing the wafer from the carrier substrate; and singulating each wafer-level optical sensor integrated circuit.

### CROSS-REFERENCE TO RELATED APPLICATIONS

This application claims priority to U.S. Provisional Patent Application No. 63/507,345, filed on Jun. 9, 2023, the contents of which are hereby incorporated by reference in their entirety.

### TECHNOLOGICAL FIELD

Example embodiments of the present disclosure relate generally to optical sensor packaging, and more particularly, to an apparatus and method for protecting an optical sensor of a glassless wafer-level package.

### BACKGROUND

The demand for semiconductors is ever-increasing as new technology requiring semiconductors is developed. Further, as electronic devices are developed, smaller, thinner form factors have become increasingly desirable and achievable. Semiconductor packages for electronic devices continue to shrink in size and be placed closer together. These semiconductor packages, as well as other components of electronic devices have some parameters of their sizes dictated by features other than the underlying semiconductor chip.

As technology enabling semiconductor chips to become smaller in all dimensions, limiting factors for semiconductor packages are no longer the chip, but instead the elements attached to the chip that form the semiconductor package. New systems, apparatuses, and method for semiconductor packaging are needed. The inventor have identified numerous areas of improvement in the existing technologies and processes, which are the subjects of embodiments described herein. Through applied effort, ingenuity, and innovation, many of these deficiencies, challenges, and problems have been solved by developing solutions that are included in embodiments of the present disclosure, some examples of which are described in detail herein.

### BRIEF SUMMARY

Various embodiments described herein relate to semiconductor packages, particularly to glassless wafer-level optical sensor packaging in a manner that protects the sensor.

In accordance with some embodiments of the present disclosure, an example method is provided. Embodiments provided herein include a method of manufacturing a glassless wafer-level optical sensor package including: forming one or more dams at least partially surrounding one or more optical sensors on a wafer; supporting the wafer on a carrier substrate via the one or more dams; forming a wafer-level optical sensor integrated circuit for each of the one or more optical sensors on the wafer by: performing a through-silicon via process on the wafer; forming an isolation layer on the wafer; and performing a passivation operation on the wafer; removing the wafer from the carrier substrate; and singulating each wafer-level optical sensor integrated circuit.

According to some embodiments, forming the one or more dams at least partially surrounding the one or more optical sensors on the wafer includes forming the one or more dams using at least one of: patterned lithography, polymer deposition, or photo-masked epoxy. According to certain embodiments, forming the one or more dams using at least one of: patterned lithography, polymer deposition, or photo-masked epoxy includes forming the one or more dams to a height of between 30 microns and 60 microns above a surface of the wafer. The carrier substrate of an example embodiment includes a glass carrier substrate, where the glass carrier substrate is configured to enable testing of the one or more optical sensors using light received at the one or more optical sensors through the glass carrier substrate.

According to some embodiments, forming the wafer-level optical sensor integrated circuit further includes forming at least one redistribution layer on the wafer. Forming the wafer-level optical sensor integrated circuit from the wafer includes, in some embodiments, performing a silicon thinning operation on the wafer before performing the through-silicon via process on the wafer. According to certain embodiments, forming the wafer-level optical sensor integrated circuit from the wafer further includes attaching one or more solder balls to one or more signal pads of the wafer level optical sensor integrated circuit. According to some embodiments, singulating each wafer-level optical sensor integrated circuit includes separating a first wafer-level optical sensor integrated circuit from a second wafer-level optical sensor integrated circuit using at least one of a mechanical saw, a laser, or a die cut.

Embodiments provided herein include a glassless wafer-level optical sensor package including: a silicon wafer; an optical sensor disposed on the silicon wafer; a dam supported on the silicon wafer and at least partially surrounding the optical sensor; and circuitry attached to the optical sensor formed using a through-silicon via process on the wafer. According to some embodiments, the glassless wafer-level optical sensor package further includes an isolation layer on the wafer opposite the optical sensor; and a passivation layer over the isolation layer. According to some embodiments, the dam is formed on the silicon wafer by at least one of patterned lithography, polymer deposition, or photo-masked epoxy.

According to certain embodiments, the dam is formed to a height between 30 microns and 60 microns above a surface of the wafer. The glassless wafer-level optical sensor package of some embodiments further includes one or more redistribution layers on the passivation layer. An overall thickness of the glassless wafer-level optical sensor package of some embodiments is between about 120 and 180 microns. An overall thickness of the glassless wafer-level optical sensor package of certain embodiments is less than 200 microns. The glassless waver-level optical sensor package of certain embodiments includes a fan-in wafer-level package.

Embodiments provided herein include a system for producing a glassless wafer-level optical sensor package including: a glass carrier substrate; a silicon wafer supported on the glass carrier substrate; an optical sensor disposed on the silicon wafer and facing the glass carrier substrate; and a dam formed on the silicon wafer and supporting the silicon wafer above the glass carrier substrate, where the dam substantially surrounds the optical sensor. According to some embodiments, the system further includes a through-silicon via process for connecting circuitry to the optical sensor. According to certain embodiments, the dam is formed using at least one of: patterned lithography, polymer deposition, or photo-masked epoxy. The dam of some embodiments is of a heigh between 30 microns and 60 microns above a surface of the silicon wafer.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF SUMMARY OF THE DRAWINGS

Having thus described certain example embodiments of the present disclosure in general terms, reference will now be made to the accompanying drawings, which are not necessarily drawn to scale, and wherein:

FIG. 1 illustrates a top view of a semiconductor package according to an example embodiment of the present disclosure;

FIG. 2 illustrates a cross-section view of a wafer-level optical sensor package both with a glass layer and without a glass layer according to example embodiments of the present disclosure;

FIG. 3 illustrates a cross-section view of a glassless wafer-level optical sensor package in transport packaging according to an example embodiment of the present disclosure;

FIG. 4 illustrates a cross-section view of a glassless wafer level optical sensor package including one or more dams to protect the optical sensor according to an example embodiment of the present disclosure;

FIG. 5 illustrates a bottom view of a glassless wafer level optical sensor package including one or more dams to protect the optical sensor according to an example embodiment of the present disclosure;

FIG. 6 illustrates a cross-section view of a glassless wafer-level optical sensor package including one or more dams to protect the optical sensor in transport packaging according to an example embodiment of the present disclosure;

FIGS. 7A-7C illustrate a manufacturing process for a glassless wafer level optical sensor package including one or more dams to protect the optical sensor according to an example embodiment of the present disclosure;

FIGS. 8A-8C further illustrate a manufacturing process for a glassless wafer level optical sensor package including one or more dams to protect the optical sensor according to an example embodiment of the present disclosure; and

FIG. 9 is a flowchart of a method of manufacturing a glassless wafer level optical sensor package including one or more dams to protect the optical sensor according to an example embodiment of the present disclosure.

### DETAILED DESCRIPTION

Some embodiments of the present disclosure will now be described more fully herein with reference to the accompanying drawings, in which some, but not all, embodiments of the disclosure are shown. Indeed, various embodiments of the disclosure may be embodied in many different forms and should not be construed as limited to the embodiments set forth herein; rather, these embodiments are provided so that this disclosure will satisfy applicable legal requirements. Like reference numerals refer to like elements throughout.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in various embodiments,” “in one embodiment,” “according to one embodiment,” “in some embodiments,” and the like generally mean that the particular feature, structure, or characteristic following the phrase may be included in at least one embodiment of the present disclosure and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments or it may be excluded.

The use of the term “circuitry” as used herein with respect to components of a system or an apparatus should be understood to include particular hardware configured to perform the functions associated with the particular circuitry as described herein. The term “circuitry” should be understood broadly to include hardware and, in some embodiments, software for configuring the hardware. For example, in some embodiments, “circuitry” may include processing circuitry, communications circuitry, input/output circuitry, and the like. In some embodiments, other elements may provide or supplement the functionality of particular circuitry.

Various embodiments of the present disclosure are directed to improved systems, apparatuses, and methods for semiconductor packages, and specifically to improved packaging for optical sensors. Optical sensors require a line-of-sight, whether direct or indirect, to the optical sensor for sensing light of any frequency. Conventionally, packaging for optical sensors include a glass layer over the optical sensor. However, as semiconductor chips have achieved exceedingly small overall sizes due to improvements in technology, the inclusion of a glass layer substantially increases an overall thickness of the semiconductor package by as much as 400 percent. Embodiments described herein provide a package, such as a wafer-level optical sensor package that omits the glass layer, while still providing protection for the optical sensor to reduce the likelihood of damage during transport. Further, omitting the glass layer provides additional improvements to the wafer-level package besides a substantial reduction in the overall thickness. A lack of a glass layer improves optical performance as there is some degree of loss of fidelity when light travels through any medium, with denser mediums such as glass potentially inducing some degree of refraction, reflection, or absorption. The production of glassless wafer-level packages further improves manufacturing efficiency as there is no opportunity for glass defects, such as occlusions, which would compromise the functionality of the optical sensor. This leads to less manufacturing waste, increased production efficiency, and reduced production cost. Further, the lack of a glass layer eliminates a component from the wafer-level package thereby reducing the overall cost of the materials used in the production of the wafer-level package.

Semiconductor packages continue to shrink in size and be utilized in environments with increasing constraints on size, such as in mobile phones, portable electronics, and the like. Shrinking semiconductor packages require all components of the overall package to decrease in size, where some components possess physical limitations on size due to one or more of existing manufacturing technology, production costs, structural requirements, or the like. An effective way of reducing the overall size of a semiconductor package is to eliminate components, if there is a possible way to otherwise provide the functionality of the eliminated components.

Wafer-level packaging provides an efficient manufacturing process through which an integrated circuit is fabricated, and components of the integrated circuit are attached to the integrated circuit before it is singulated into an individual circuit. The components such as top and bottom layers of the packaging and solder bumps are attached to the integrated circuit through a process that does not require handling of individual integrated circuits. This process enables efficient and consistent packaging assembly to the integrated circuit without requiring an individual integrated circuit to be handled and aligned in order to assemble the components thereon. Fan-out wafer-level packaging employs a similar technique; however, the integrated circuit is singulated before at least some components of the wafer-level package are attached to the integrated circuit. Fan-out wafer-level packaging enables portions of the overall semiconductor package to be larger than the integrated circuit itself (e.g., the die cut wafer). Embodiments described herein can be employed in wafer-level packaging and in fan-out wafer-level packaging with some modification to the manufacturing process. However, the end product remains essentially the same.

Wafer-level packaging enables the manufacturing of an integrated circuit in a streamlined and efficient process while producing an integrated circuit that has a highly compact overall size. Various types of sensors are produced as wafer-level packages; however, wafer-level optical sensors are unique in requiring visibility, whether direct or indirect, to an environment of the optical sensor. Wafer-level optical sensors can be employed for light sensors (e.g., infrared), biometric authentication sensors, environmental sensing, and cameras, for example. Each of these types of sensors require the wafer-level optical sensor to have a line-of-sight, directly or through optics, to a target of the optical sensor. This requirement dictates the packaging of the wafer-level optical sensor within an end-device, such as a mobile phone.

Electronic devices, such as mobile phones, are highly portable and frequently carried throughout a user's day. As such, the size of a mobile phone or other portable electronic device is critical to the portability and use of such a device. These electronic devices have very high levels of functionality and are required to be robustly designed to stand up to frequent use and often, unintentional abuse and wear. Thus, the structure of theses electronic devices requires some degree of rigidity while maintaining a small form factor. The substantially rigid chassis of an electronic device which carries the hardware components thereof (e.g., the sensors, communications modules, speakers, cameras, screen, etc.) becomes a substantial component of the overall size, which limits the available space for the hardware components. The competing hardware components need to be sized to fit within the small form factor, otherwise components will be omitted, which adversely impacts functionality and desirability of the electronic device. As such, a small form factor for a wafer-level package for one or more sensors is highly desirable, and smaller components enable the electronic device form factor to be made smaller and/or enables the inclusion of more components increasing the functionality of the electronic device.

Wafer-level packaging has improved integrated circuits in a number of ways including the relative thickness of an integrated circuit. Wafer-level packaging enables integrated circuits to be manufactured in a very compact form factor with a thickness of less than 100 microns.

Wafer-level optical sensors generally include an optical glass layer over the sensing component of the optical sensor to protect the optical sensor while also enabling light to reach the sensor. This glass becomes an integral component of the wafer-level optical sensor and often represents a substantial portion of a thickness of the wafer-level optical sensor. A wafer-level optical sensor can be as thin as around 80 microns. The inclusion of an optical glass layer over the sensor can add over 300 microns to the overall thickness of the wafer-level optical sensor. While the optical glass layer provides a degree of protection for the optical sensor, the substantial increase in thickness runs counter to a significant benefit of wafer-level packaging in general, which is the overall packaging thickness. Devices such as mobile phones employ a relatively thin form factor, with a substantial portion of the thickness of the device dedicated to structural elements along with front and back layers that need to be robust to frequent use. Thus, the thickness of all components within such a device is critical to the overall packaging dimensions.

While it is possible to produce wafer-level optical sensors without an optical glass layer, the optical sensor of a wafer-level optical sensor is left exposed and vulnerable to damage. Embodiments of the present disclosure provide a process of producing a wafer-level optical sensor without an optical glass layer, while adding protection to the sensor outside of a line-of-sight of the sensor.

Embodiments provided herein include a glassless wafer-level optical sensor that substantially reduces an overall thickness of the optical sensor, improving packaging efficiency within an electronic device. Further, embodiments provide a mechanism through which the optical sensor is protected to mitigate damage during production, transport, and final assembly within an electronic device.

Wafer-level optical sensors without a glass layer have several benefits over those including an optical glass layer. The overall packaging thickness of a wafer-level optical sensor without an optical glass layer can reduce an overall thickness of the sensor package from about 300-400 microns to about 100-150 microns. This substantial reduction in thickness is significant, particularly from a packaging standpoint within compact form factor devices. The optical sensor performance of a wafer-level optical sensor without optical glass is improved as removal of the optical glass layer reduces refraction, reflection, and potential defects in the glass layer that adversely affect optical sensor performance. A cost of manufacture of the wafer-level optical sensor without the optical glass layer is reduced on two fronts. The lack of an optical glass layer reduces cost through a reduction in material required to produce the wafer-level optical sensor. Further, the potential for defects of manufactured wafer-level optical sensors is reduced as the glass layer is a potential source of defects through blemishes, scratches, and cracks among other defects.

As the removal of the optical glass layer can increase the vulnerability of the optical sensor, embodiments provided herein provide a manufacturing method that produces a wafer-level optical sensor that includes a degree of protection for the optical sensor. The wafer-level optical sensor, instead of a glass layer over the optical sensor, includes a dam surrounding the optical sensor outside of a line-of-sight of the optical sensor. This dam helps shield the optical sensor from damage.

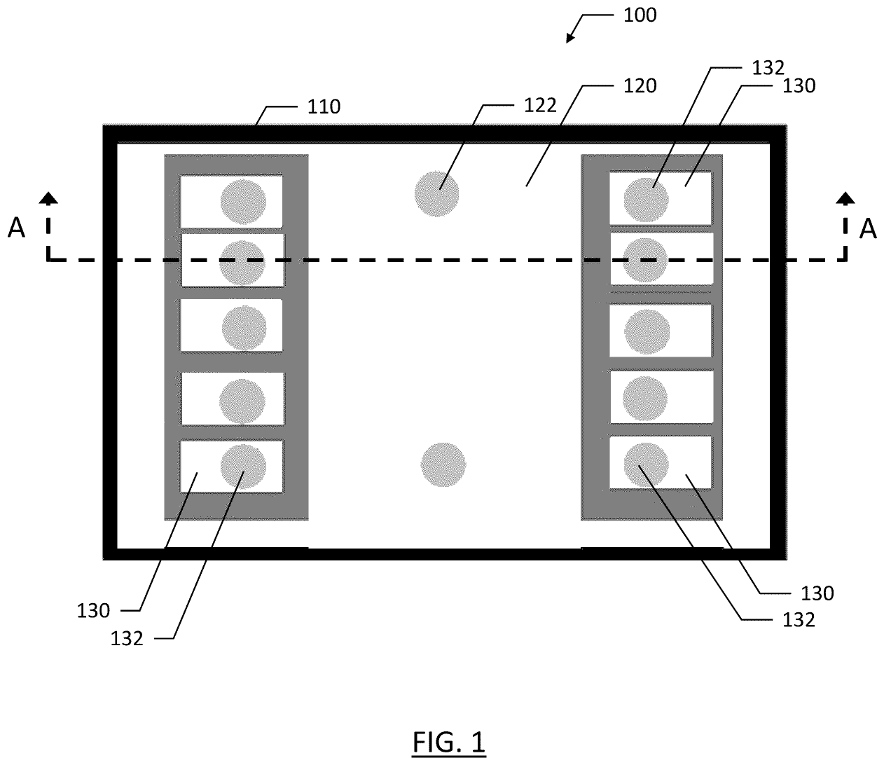

FIG. 1 illustrates a top-view of an example embodiment of a semiconductor package in accordance with one or more embodiments of the present disclosure. A semiconductor package 100 may include a dielectric layer 110, a ground plane 120, a plurality of signal pads 130, and a plurality of solder balls, such as ground plane solder balls 122 and signal pad solder balls 132. The dielectric layer may be a polyimides (PI) and/or polybenzoxazoles (PBO) material. FIG. 1 further depicts section line A-A representing a section line where cross-sectional views of subsequent figures are taken of various embodiments.

It will be readily appreciated that while only several of the signal pads 130 and signal pad solder balls 132 are referenced with numbers, the semiconductor package 100 may include a plurality of each as shown in FIG. 1. Each of the signal pads 130 may be separated from the ground plane 120 by one or more layers and/or portions of dielectric material (e.g., dielectric layer 110). When the semiconductor package 100 is used in an electronic device, the plurality of solder balls (e.g. ground plane solder balls 122 and signal pad solder balls 132) may connect the semiconductor package to other circuitries of the electronic device. While the semiconductor package 100 is illustrated as a rectangle, it will be readily appreciated that the semiconductor package 100 may take other shapes and/or dimensions, particularly as required by an electronic device. The semiconductor package 100 of FIG. 1 is an example of a view of various semiconductor configurations as described herein, such that further figures will be described with views taken along section line A-A while the cross-section views may depict different embodiments of a semiconductor package 100.

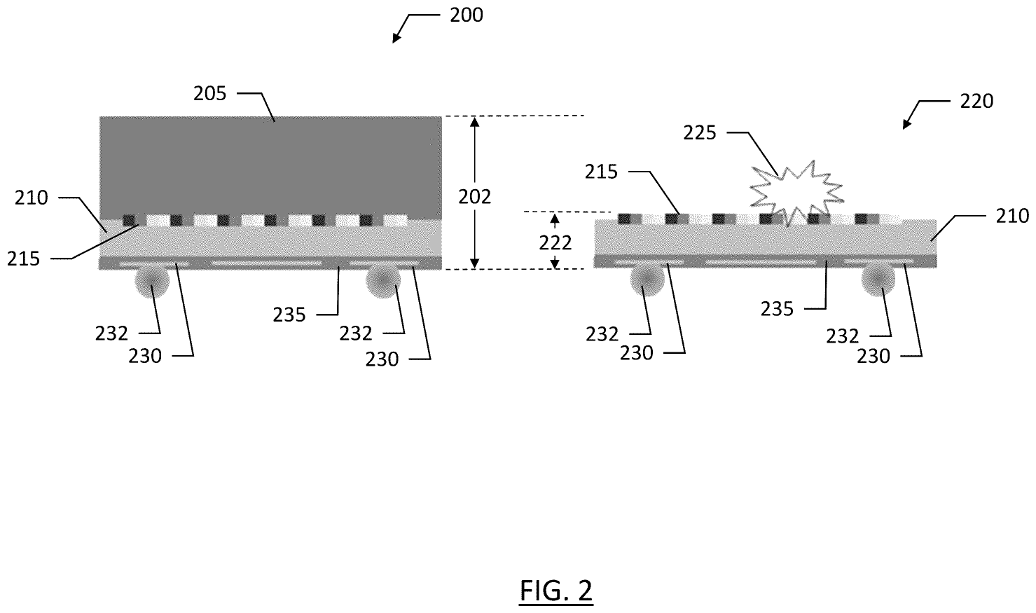

FIG. 2 illustrates two cross section views of semiconductor packages in the form of optical sensor wafer-level packages, taken along a line in the respective semiconductor package A-A as shown in FIG. 1. First optical sensor wafer-level package 200 is illustrated including the semiconductor chip 210, which may be, for example, a silicon chip. The first optical sensor wafer-level package 200 further includes optical sensor 215 extending across a portion of the semiconductor chip 210. Opposite the optical sensor 215 is the dielectric layer 235 along with signal pads 230 and signal pad solder balls 232. The first optical sensor wafer-level package 200 further includes glass layer 205 covering and protecting the optical sensor 215.

FIG. 2 also illustrates a cross section view of a second optical sensor wafer-level package 220 that includes the semiconductor chip 210, the dielectric layer 235, the signal pads 230 and signal pad solder balls 232. The second optical sensor wafer-level package 220 lacks the glass layer of the first optical sensor wafer-level package 210, which exposes the optical sensor 215 to sensor damage 225, such as through an impact. The optical sensor 315 of the second optical wafer-level package 220 can be damaged due to various causes from production through to final assembly of the electrical device into which the package is installed. Further, the optical sensor 315 can be subject to damage within a device depending upon the type of device and exposure of the optical sensor to other elements. While the second optical sensor wafer-level package 220 is susceptible to damage, the overall thickness 222 of the second optical sensor wafer-level package 220 is substantially less than the overall thickness 202 of the first optical sensor wafer-level package 200 including the glass layer 205.

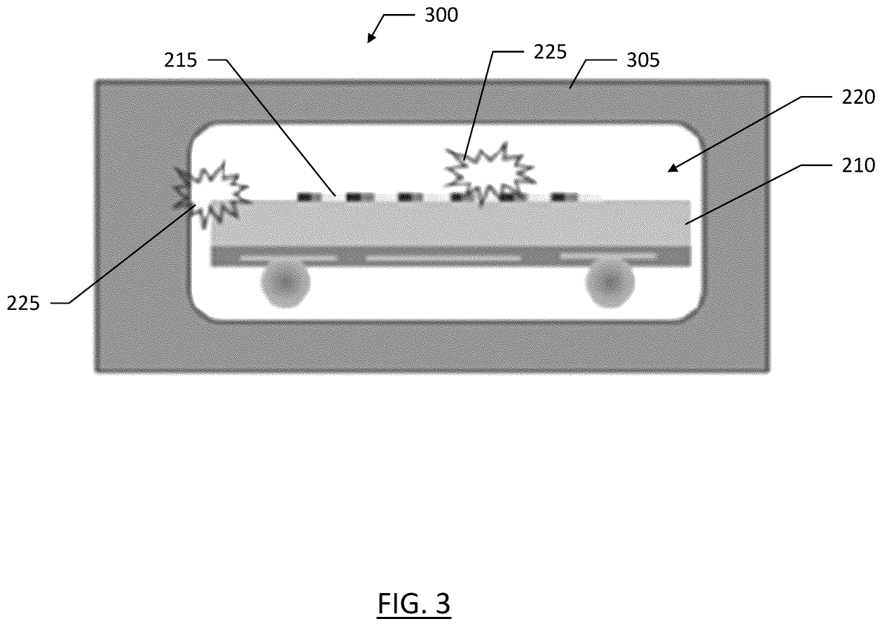

FIG. 3 illustrates the second optical wafer-level package 220 packed in packaging 305 for transport as a packaged semiconductor package 300. During the packaging operation where the wafer-level package gets inserted into packaging 305, damage can occur. Similarly, when the wafer-level package is transported, unpacked, and assembled, there are opportunities for sensor damage 225. Impact to the optical sensor 215 can compromise the integrity of the optical sensor and reduce or eliminate the functionality of the optical sensor 215.

While it is desirable to omit the glass layer from the wafer-level package as illustrated with respect to FIG. 2, doing so renders the optical sensor more vulnerable to damage. Embodiments described herein mitigate the vulnerability to enable glassless wafer-level optical sensor packaging to obtain the benefits of a glassless package while reducing the likelihood of damage to the optical sensor due to the vulnerability a lack of a glass layer presents.

Embodiments described herein provide a dam around some or all of the optical sensor of a glassless wafer-level optical sensor package to protect the optical sensor through reducing vulnerabilities of the wafer-level optical sensor package. Further, embodiments reap the benefits of omitting the glass layer while retaining some degree of physical protection of the optical sensor.

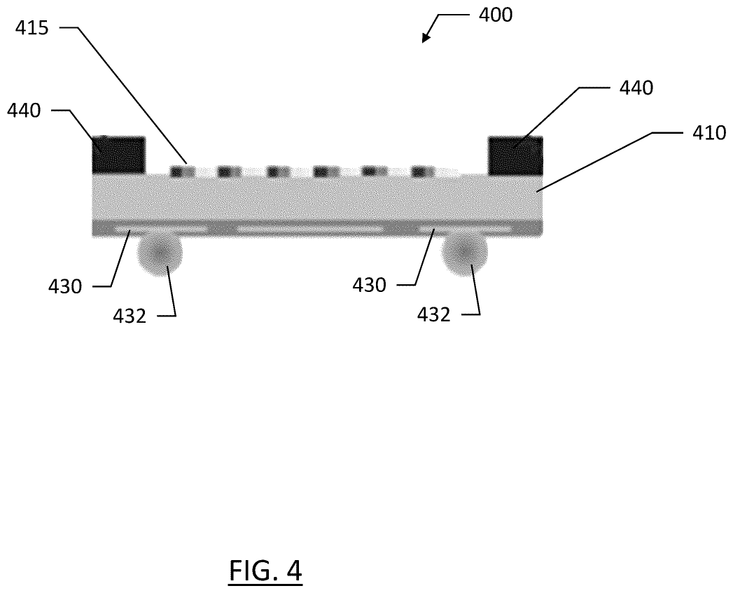

FIG. 4 illustrates an example embodiment of the present disclosure including a glassless wafer-level optical sensor package 400 taken along a cross-section of a semiconductor package as shown in FIG. 1. The glassless wafer-level optical sensor package 400 includes the semiconductor chip 410, the optical sensor 415, the signal pads 430, and the signal pad solder balls 432. Also shown are dams 440 on opposing sides of the optical sensor 415. The dams can form a continuous frame or border about the optical sensor 415. However, in some embodiments, the dams 440 can be discontinuous, and extend only along portions of one or more sides of the optical sensor 415. According to an embodiment in which the dams 440 are not continuous, the dams may extend along portions of each side of the optical sensor to retain the protective function of the dams described herein.

The dams 440 illustrated in FIG. 4 protect the optical sensor 415 from impacts approaching the optical sensor from above and beside the optical sensor, which is a primary direction of damaging contact. The dams 440 also serve to preclude a portion of packaging from contacting the optical sensor 415 by the dams suspending the packaging portion above the optical sensor. For example, a portion of the packaging component contacting the both dams would span both dams and be suspended above the optical sensor 415 as the dams are at a greater height than the optical sensor 415.

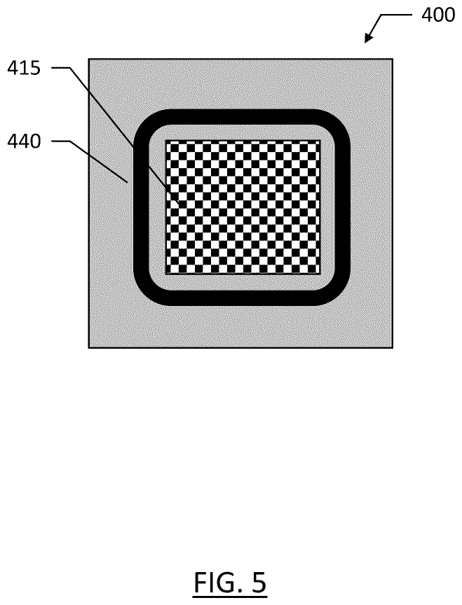

FIG. 5 illustrates a top view of the glassless wafer-level optical sensor package 400 of FIG. 4, illustrating an example embodiment of how the dam 440 can surround the optical sensor 415. The dam 440 can be spaced from the optical sensor 415, or abut the optical sensor 415. Abutting the optical sensor with the dam may provide additional or better protection of the sensor; however, such positioning can adversely impact the field-of-view of the optical sensor in some embodiments. Further, while the dam 440 of FIG. 5 has rounded corners, embodiments can include sharp corners, particularly if the dam 440 is abutting the optical sensor 415.

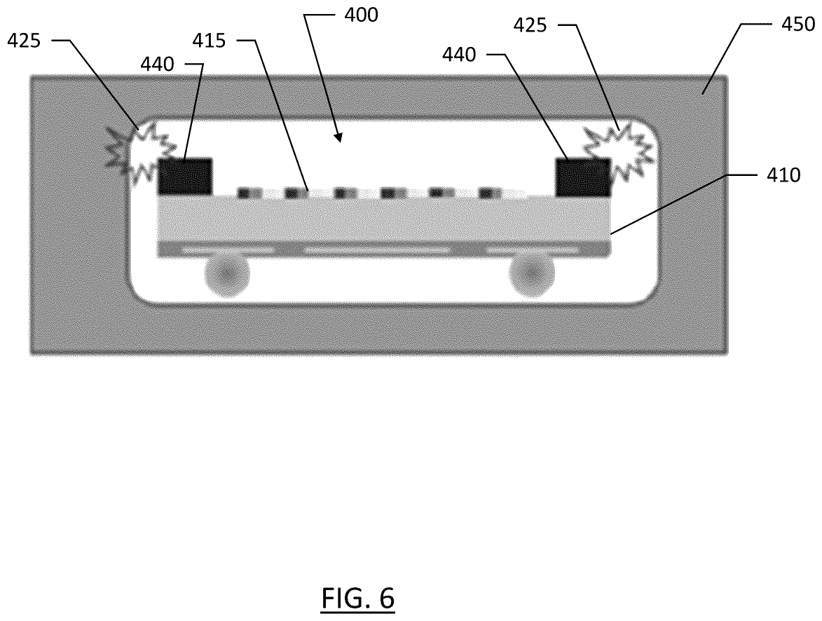

FIG. 6 illustrates the glassless wafer-level optical sensor package 400 within packaging 450. As illustrated, the dams 440 aid in blocking damaging impacts from reaching the optical sensor 415. The outer edges of the dams 440 are generally first contacted by any impacts 425 in such a way that the optical sensor 415 itself is not contacted and is therefore not damaged by impacts that might otherwise damage the optical sensor, such as in embodiments shown in FIG. 3. It should be readily appreciated that the embodiments of the systems and apparatuses, described herein, particularly for the shape and size of the dam formed about the optical sensor, may be configured in various additional and alternative manners in addition to those expressly described herein.

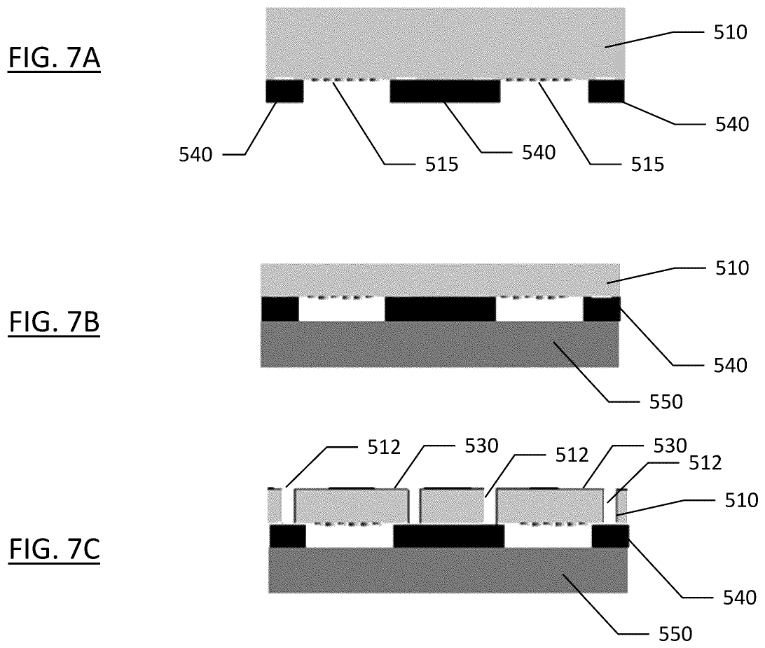

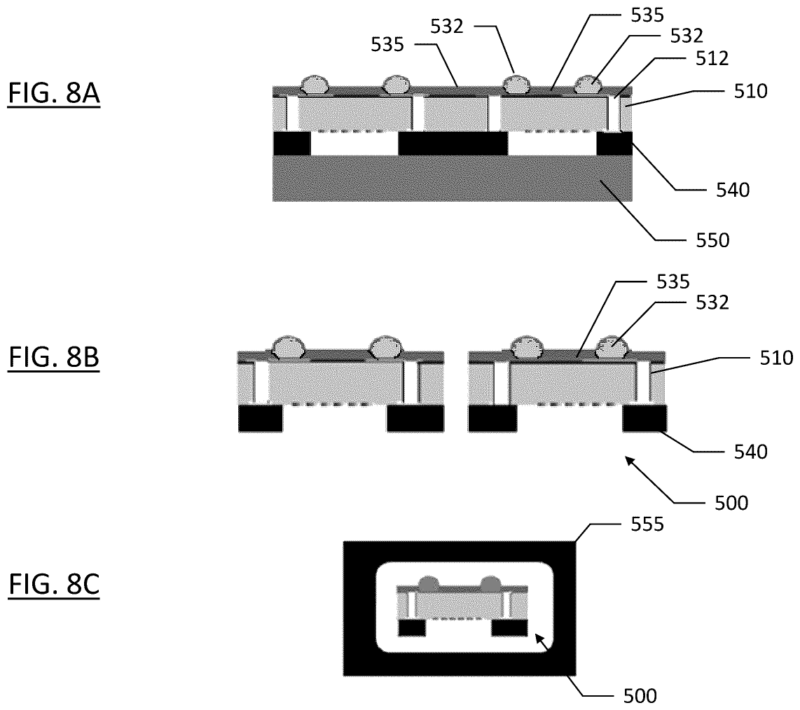

FIGS. 7A-C and FIGS. 8A-C illustrate a manufacturing process to produce embodiments described herein of glassless wafer-level optical sensor packaging. While the illustrated and described manufacturing method is not the only possible method of manufacture, embodiments described herein can employ embodiments of the manufacturing process of the following disclosure.

FIG. 7A illustrates a silicon wafer 510 including two optical sensors 515 and dams 540 formed therebetween. The dams 540 can be deposited through various mechanisms depending upon the material used for the dams. For example, the whole wafer 510 including the optical sensors 515 can be covered by a photo-cure epoxy, where a mask is applied to shield areas that are not to be cured (e.g., non-dam areas including the optical sensors). A light can be exposed to the masked photo-cure epoxy, with the epoxy curing in the unmasked dam areas. The remaining uncured epoxy can be washed away to reveal only traces of cured epoxy in the form of dams 540. Other materials known in the art can be used through processes such as dry-etched material, polymer deposition, lithography, or the like. Depending upon the method of formation of the dams 540, a top surface of the dams may be machined to obtain a substantially planar surface of the dam elements.

FIG. 7B illustrates a following operation in the manufacturing process where the silicon wafer 510 is mounted to a carrier substrate 550 of a carrier handling material at the top surfaces of the dams 540. The silicon wafer is shown in cross-section, similar to the cross section line A-A of FIG. 1. The carrier handling material in an example embodiment is a glass material. Using a glass material for the carrier substrate 550 allows testing of the optical sensors 515 by providing light to the sensors through the glass carrier substrate 550 during the manufacturing process. The silicon wafer is thinned, through a process such as grinding and/or polishing, to a finished thickness, which can be around 80-150 microns, for example. The silicon wafer 510 is then ready for processing using a TSV (through-silicon via). The TSV process is performed as shown in FIG. 7C and creates a vertical electrical connection that passes through the silicon wafer 510 shown at 512 to form interconnections. The TSV process eliminates wire bonds and enables higher density interconnects while retaining a small package size. This process forms connections between the optical sensor 515 and sensor pads 530. An isolation process is then performed using an isolation layer deposited on a surface of the silicon wafer 510 outside of the sensor pads 530. At this stage, a redistribution layer (RDL) may be employed to position sensor pads in the appropriate positions for the intended use.

FIG. 8A illustrates the deposition of a passivation layer 535 over the wafer except at the position of the sensor pads 530. This creates a shield that is applied as a micro-coating such that the surface of the wafer-level optical sensor package is less readily affected or corroded by the environment. The sensor solder balls 532 are applied to the sensor pads 530 to serve as connection points to the optical sensor 515.

FIG. 8B illustrates where the wafer-level optical sensor packages are separated from the carrier substrate and singluated to form individual glassless wafer-level optical sensor packages. These individual glassless wafer-level optical sensor packages 500. The singluated, glassless wafer-level optical sensor packages 500 are then packed into packaging 555.

As noted above, the use of a glass carrier substrate 550 benefits the manufacturing process as the optical sensors can be tested during the manufacturing process, before the sensor packages are singluated. This enables testing of the optical sensors beginning as early as after the TSV process to ensure functionality and a proper connection is made before subsequent operations are performed. Sensor testing can further be performed before singulation, allowing the sensor packages to be tested for functionality before being finally packaged to ensure all sensor packages work properly when transported to their destination for assembly into an electronic device.

The glassless wafer-level optical sensors of example embodiments provided herein provide substantial advantages over wafer-level optical sensors employing a glass layer. A substantial advantage to a glassless wafer-level optical sensor is a substantial reduction in an overall thickness of the sensor package. The wafer-level optical sensor itself may be of a thickness of about 80 microns to about 150 microns, whereas the glass layer can add 300 microns or more to the overall thickness. Removing the glass layer enables a wafer-level optical sensor having a thickness of about 120 to 180 microns, and more specifically, about 130 to 160 microns in total, with or without the solder ball. The thickness of the dam described herein can be in a range of about 30-60 microns generally. A reduction in sensor thickness of more than 300 microns is a significant advancement in the production of wafer-level optical sensors, and to do so with a glassless wafer-level optical sensor that retains some degree of protection for the optical sensor is a further significant development employing the embodiments described herein. This reduction in overall thickness can dramatically reduce the amount of room such a sensor occupies within an electronic device, providing greater design freedom with the electronic device and enabling a smaller, thinner overall device size, which has proven highly desirable in portable electronic devices.

In addition to the size advantage, embodiments described herein of glassless wafer-level optical sensor packaging have superior optical performance relative to those employing a glass layer. When light travels through any medium there exists a possibility for refraction, reflection, and absorption into the medium. Light travels most efficiently in a vacuum, but can also travel efficiently in ambient air environments. Dense materials can pose greater challenges to efficient light travel, such that materials such as glass can reflect, refract, and absorb light to decrease the efficiency of light traveling through the glass and reaching the optical sensor. Thus, omitting the glass layer is inherently more efficient than having the glass layer.

Beyond size and efficiency, improvements also include less waste in sensor production. Glass manufacturing has become efficient and glass layers used in optical sensors is generally of a very high quality. However, even high quality glass layers can include occlusions, chips, dirt, debris, or other issues that reduce the effectiveness of an optical sensor. An optical sensor produced with defective glass has lower accuracy and may not meet minimum quality standards. As such, a produced wafer-level optical sensor package with defective glass may be rejected and become waste, decreasing the efficiency with which the sensor packages are produced.

In addition to these benefits, the lack of a glass layer reduces the number of components in the sensor, and saves cost of the sensor by not requiring the glass layer. This decreases the cost of manufacture of the optical sensor package thereby improving the efficiency of manufacturing and production.

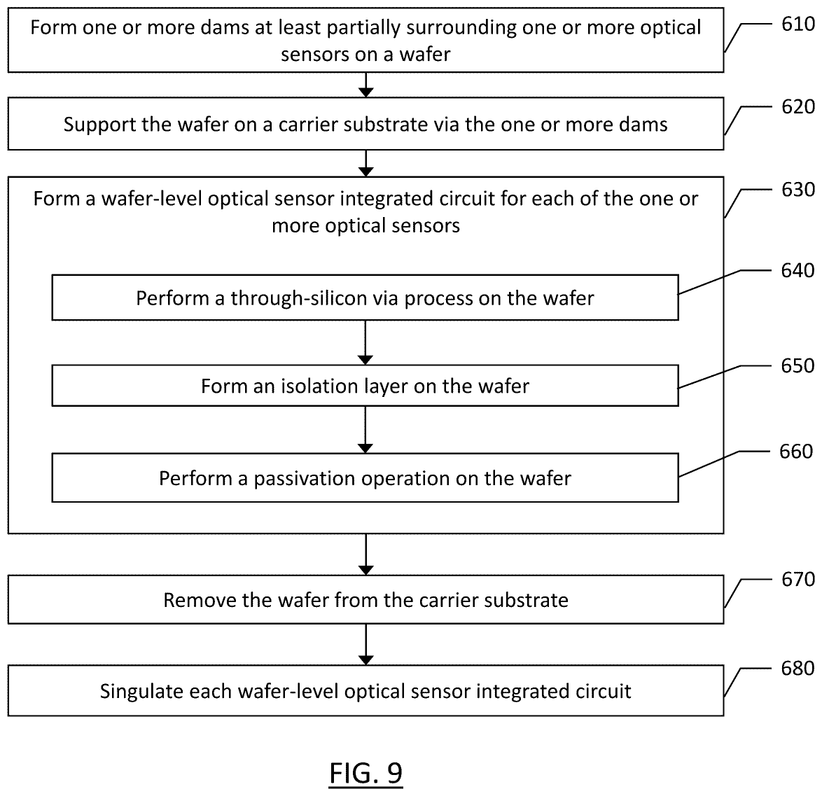

FIG. 9 illustrates an example block diagram of a flowchart of operations for manufacturing a glassless wafer-level optical sensor package in accordance with one or more embodiments of the present disclosure. In various embodiments one or more of the operations may be omitted or repeated. It will also be appreciated that other operations not described herein may also occur. According to the illustrated embodiment, one or more dams are formed at operation 610 to at least partially surround one or more optical sensors on a wafer. The wafer is supported on a carrier substrate via the one or more dams at 620. At 630, a wafer-level optical sensor integrated circuit is formed for each of the one or more optical sensors. This includes performing a through-silicon via process on the wafer at 640, forming an isolation layer on the wafer at 650, and performing a passivation operation on the wafer at 660. The wafer is removed from the carrier substrate at 670, and each wafer-level optical sensor is singulated at operation 680.

Operations and/or functions of the present disclosure have been described herein, such as in flowcharts or figures associated with flowcharts. While operations and/or functions are illustrated in a particular order, this should not be understood as requiring that such operations and/or functions be performed in the particular order shown or in sequential order, or that all illustrated operations be performed, to achieve desirable results. In certain circumstances, operations and/or functions in alternative ordering may be advantageous. In some cases, the actions recited in the claims may be performed in a different order and still achieve desirable results. Thus, while particular embodiments of the subject matter have been described, other embodiments are within the scope of the following claims.

While this specification contains many specific embodiments and implementation details, these should not be construed as limitations on the scope of any disclosures or of what may be claimed, but rather as descriptions of features specific to particular embodiments of particular disclosures. Certain features that are described herein in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

While this detailed description has set forth some embodiments of the present invention, the appended claims cover other embodiments of the present invention which differ from the described embodiments according to various modifications and improvements.

Within the appended claims, unless the specific term “means for” or “step for” is used within a given claim, it is not intended that the claim be interpreted under 35 U.S.C. § 112, paragraph 6.

1. A method of manufacturing a glassless wafer-level optical sensor package comprising:
forming one or more dams at least partially surrounding one or more optical sensors on a wafer;
supporting the wafer on a carrier substrate via the one or more dams;
forming a wafer-level optical sensor integrated circuit for each of the one or more optical sensors on the wafer by:
performing a through-silicon via process on the wafer;
forming an isolation layer on the wafer; and
performing a passivation operation on the wafer;
removing the wafer from the carrier substrate; and
singulating each wafer-level optical sensor integrated circuit.

2. The method of claim 1, wherein forming the one or more dams at least partially surrounding the one or more optical sensors on the wafer comprises:
forming the one or more dams using at least one of: patterned lithography, polymer deposition, or photo-masked epoxy.

3. The method of claim 2, wherein forming the one or more dams using at least one of:
patterned lithography, polymer deposition, or photo-masked epoxy comprises forming the one or more dams to a height of between 30 microns and 60 microns above a surface of the wafer.

4. The method of claim 1, wherein the carrier substrate comprises a glass carrier substrate, wherein the glass carrier substrate is configured to enable testing of the one or more optical sensors using light received at the one or more optical sensors through the glass carrier substrate.

5. The method of claim 1, wherein forming the wafer-level optical sensor integrated circuit from the wafer further comprises:
forming at least one redistribution layer on the wafer.

6. The method of claim 1, wherein forming the wafer-level optical sensor integrated circuit from the wafer further comprises:
performing a silicon thinning operation on the wafer before performing the through-silicon via process on the wafer.

7. The method of claim 1, wherein forming the wafer-level optical sensor integrated circuit from the wafer further comprises:
attaching one or more solder balls to one or more signal pads of the wafer-level optical sensor integrated circuit.

8. The method of claim 1, wherein singulating each wafer-level optical sensor integrated circuit comprises separating a first wafer-level optical sensor integrated circuit from a second wafer-level optical sensor integrated circuit using at least one of a mechanical saw, a laser, or a die cut.

9. A glassless wafer-level optical sensor package comprising:
a silicon wafer;
an optical sensor disposed on the silicon wafer;
a dam supported on the silicon wafer and at least partially surrounding the optical sensor; and
circuitry attached to the optical sensor formed using a through-silicon via process on the wafer.

10. The glassless wafer-level optical sensor package of claim 9, further comprising:
an isolation layer on the wafer opposite the optical sensor; and
a passivation layer over the isolation layer.

11. The glassless wafer-level optical sensor package of claim 9, wherein the dam is formed on the silicon wafer by at least one of patterned lithography, polymer deposition, or photo-masked epoxy.

12. The glassless wafer-level optical sensor package of claim 11, wherein the dam is formed to a height of between 30 microns and 60 microns above a surface of the wafer.

13. The glassless wafer-level optical sensor package of claim 9, further comprising one or more redistribution layers on the passivation layer.

14. The glassless wafer-level optical sensor package of claim 9, wherein an overall thickness of the glassless wafer-level optical sensor package is between about 120 and 180 microns.

15. The glassless wafer-level optical sensor package of claim 9, wherein an overall thickness of the wafer-level optical sensor package is less than 200 microns.

16. The glassless wafer-level optical sensor package of claim 9, wherein the glassless wafer-level optical sensor package comprises a fan-in wafer-level package.

17. A system for producing a glassless wafer-level optical sensor package comprising:
a glass carrier substrate;
a silicon wafer supported on the glass carrier substrate;
an optical sensor disposed on the silicon wafer and facing the glass carrier substrate; and
a dam formed on the silicon wafer and supporting the silicon wafer above the glass carrier substrate, wherein the dam substantially surrounds the optical sensor.

18. The system of claim 17, further comprising:
a through-silicon via process for connecting circuitry to the optical sensor.

19. The system of claim 17, wherein the dam is formed using at least one of: patterned lithography, polymer deposition, or photo-masked epoxy.

20. The system of claim 17, wherein the dam is of a height between 30 microns and 60 microns above a surface of the silicon wafer.
